(19) United States
(12) Patent Application Publication
(10) Pub. No.: US 2025/0179636 A1
(43) Pub. Date: Jun. 5, 2025

(54) GAS INTAKE DEVICE, THIN FILM DEPOSITION DEVICE, AND THIN FILM DEPOSITION METHOD

(71) Applicant: SwaySure Technology Co., Ltd., Shenzhen (CN)

(72) Inventor: Yingying ZHANG, Shenzhen (CN)

(21) Appl. No.: 18/811,430

(22) Filed: Aug. 21, 2024

(30) Foreign Application Priority Data
Nov. 30, 2023 (CN) 202311636391.1
Nov. 30, 2023 (CN) 202323271860.2

(51) Int. Cl. C23C 16/455; C23C 16/52

(52) U.S. Cl. CPC C23C 16/45561; C23C 16/45589; C23C 16/52

(57) ABSTRACT

A gas intake device is connected to a gas supply device. The gas intake device includes: a gas intake assembly for inputting reaction gas supplied by the gas supply device into a reaction chamber; and a velocity regulation assembly provided between the gas intake assembly and the gas supply device or at a gas outlet end of the gas intake assembly, for increasing a velocity of the reaction gas being input into the reaction chamber. Since the velocity of the reaction gas being input into the reaction chamber is increased, a point on the wafer at which a vector sum of the velocity of the point and the gas intake velocity of the reaction gas is 0 is eliminated.

### CROSS-REFERENCE TO RELATED APPLICATIONS

This application claims priority to a Chinese Patent Application 202311636391.1, filed Nov. 30, 2023, and a Chinese Patent Application 202323271860.2, filed Nov. 30, 2023, the entire disclosures of which are incorporated herein by reference.

### TECHNICAL FIELD

The present application relates to the technical field of semiconductor manufacturing device, and particularly to a gas intake device, a thin film deposition device, and a thin film deposition method.

### BACKGROUND

When a thin film deposition device deposits a thin film, a wafer is placed on a base of a reaction chamber for deposition. The reaction gas is input into the reaction chamber from one side of the reaction chamber in a first direction. The reaction gas not completely exhausted is discharged from another side of the reaction chamber in a first direction. The reaction gas forms a gas retention layer on the wafer, and the smaller the thickness of the gas retention layer on the wafer, the smaller the thickness of the film layer formed by deposition. As the thickness of the gas retention layer is not uniform, the thickness of the film layer formed by deposition is also not uniform.

In the existing thin film deposition device, a compensation gas is input into the reaction chamber along the second direction of the reaction chamber, and the second direction is perpendicular to the first direction. Although the solution of inputting the compensation gas is adopted, the problem of the unevenness of the thickness of the film layer can be improved at a certain extent, an input of the compensation gas increases the total reaction gas, which leads to a great increase in the difficulty of maintaining the process parameters of the reaction gas. And although the solution of inputting the compensation gas is adopted, it can only compensate for the thickness of the film layer at the edge region of the wafer, and cannot guarantee the uniformity of the thickness of the entire film layer.

### SUMMARY

There are provided a gas intake device, a thin film deposition device, and a thin film deposition method to at least improve the problem of uneven thickness of the deposited film layer, according to embodiments of the present disclosure. The technical solution is as below.

According to a first aspect of embodiments of the present application, there is provided a gas intake device, the gas intake device is connected to a gas supply device, the gas intake device includes:
a gas intake assembly, for inputting reaction gas supplied by the gas supply device into a reaction chamber; and
a velocity regulation assembly, provided between the gas intake assembly and the gas supply device or at a gas outlet end of the gas intake assembly, for increasing a velocity of the reaction gas being input into the reaction chamber.

According to a second aspect of embodiments of the present application, there is provided a thin film deposition device, including the gas intake device, and the reaction chamber connected to the gas intake device.

According to a third aspect of embodiments of the present application, there is provided a thin film deposition method, which includes:
providing a thin film deposition device, the thin film deposition device includes a gas supply device, a gas intake device and a reaction chamber connected in sequence;
placing a wafer on a base of the reaction chamber, and inputting reaction gas to the reaction chamber by the gas intake device and driving the wafer to rotate by the base;
obtaining a base intake velocity of an intake assembly of the gas supply device, the base intake velocity is positively correlated with a flow of the reaction gas supplied by the gas supply device, and the base intake velocity is negatively correlated with a flow area of the gas intake assembly;
obtaining a rotational velocity of the wafer, and calculating an outer edge linear velocity of the wafer based on the rotational velocity of the wafer and a radius of the wafer; and
comparing the base intake velocity and the outer edge linear velocity, increasing a gas intake velocity of the reaction gas where the base intake velocity is less than the outer edge linear velocity.

It should be understood that the above general description and the detailed description that follows are exemplary and explanatory only and do not limit the present disclosure.

### BRIEF DESCRIPTION OF THE DRAWINGS

The accompanying drawings herein are incorporated into and form a part of the specification, illustrate embodiments in accordance with the present application, and are used in conjunction with the specification to explain the principles of the present application. It will be apparent that the accompanying drawings in the following description are only some of the embodiments of the present application, and that other accompanying drawings may be obtained for those skilled in the art from these drawings without any creative labour.

FIG. 1 is a pictorial diagram of a thin film deposition process.

FIG. 2 is a distribution graph of absolute values of relative velocity in a diameter direction of the wafer in FIG. 1.

FIG. 3 is a distribution graph of relative velocity in a radius direction of the wafer in FIG. 1.

FIG. 4 is a schematic diagram of a connection between the rectifier cover and the reaction chamber in an embodiment of the present application.

FIG. 5 is a distribution graph of absolute values of relative velocity in the diameter direction of the wafer in FIG. 4.

FIG. 6 is a graph of the distribution of relative velocity in the radius direction of the wafer in FIG. 4.

FIG. 7 is a schematic diagram of a wind paddle connected to the reaction chamber in an embodiment of the present application.

FIG. 8 is a schematic diagram of the connection between a pressure control valve and the reaction chamber in an embodiment of the present application.

FIG. 9 is a schematic structural view of the gas intake device in an embodiment of the present application.

FIG. 10 is a flowchart of the thin film deposition method in the embodiment of the present application.

### DETAILED DESCRIPTION OF THE EMBODIMENTS

Embodiments will now be described more fully with reference to the accompanying drawings. However, the embodiments can be implemented in a variety of forms and should not be construed as limitation to the examples set forth herein; rather, the provision of these embodiments allows the present application to be more comprehensive and complete and conveys the idea of the embodiments in a comprehensive manner to those skilled in the art.

In addition, the described features, structures, or characteristics may be combined in one or more embodiments in any suitable manner. In the following description, many specific details are provided thereby giving a full understanding of the embodiments of the present application. However, those skilled in the art will realize that it is possible to practice the technical embodiments of the present application without one or more of the specific details, or that other methods, components, devices, steps, etc. may be employed. In other cases, the well-known methods, devices, implementations, or operations are not shown or described in detail to avoid blurring aspects of the present application.

The present application is described in further detail below in connection with the accompanying drawings and specific embodiments. It should be noted herein that the technical features involved in the various embodiments of the present application described below may be combined with each other as long as they do not constitute a conflict with each other. The embodiments described below by reference to the accompanying drawings are exemplary and are intended to be used for explaining the present application and are not to be construed as a limitation to the present application.

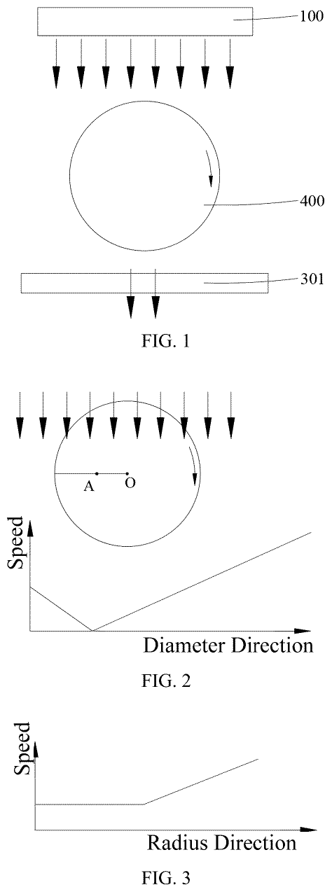

Referring to FIG. 1, when a thin film deposition device deposits a thin film, a wafer 400 is placed on a base in a reaction chamber for deposition. A gas supply device provides a reaction gas at a preset flow. A gas intake device 100 inputs the reaction gas into the reaction chamber, and the reaction gas not completely exhausted is discharged from a gas outlet 301 of the reaction chamber. The reaction gas forms a gas retention layer on the wafer 400. The smaller the thickness of the gas retention layer on the wafer 400, the smaller the thickness of the film layer formed by deposition. As the thickness of the gas retention layer is not uniform, the thickness of the film layer formed by deposition is also not uniform. When the thin film deposition device deposits a thin film, the wafer 400 is driven by the base to rotate within the reaction chamber, and the uniformity of the thickness of the film layer formed by deposition can be improved.

Referring to FIGS. 1 and 2, during a clockwise rotation of the wafer 400, a vector of the gas intake velocity of the reaction gas is opposite to a vector of a velocity of a point in a left radius of the wafer 400. The gas supply device provides the reaction gas at a preset flow. The gas intake velocity of the reaction gas and the gas flow are positively correlated under the condition that the diameter of the gas supply pipe is constant. In order to improve the uniformity of the thickness of the film layer formed by deposition, the wafer 400 needs to rotates within a preset rotation velocity range.

The applicant finds that under a preset flow and a preset rotation velocity of the wafer 400, there exists a reference point A on the left radius of the wafer 400, where the vector sum of the velocity of the reference point A and the gas intake velocity of the reaction gas is 0.

It is to be noted that, due to the limitation of the flow of the reaction gas supplied by the gas supply device, the gas intake velocity of the reaction gas is less than the outer edge linear velocity of the wafer 400. At other points outside the left radius of the wafer 400, the velocity vector of the wafer 400 can be decomposed into two velocity vectors, one along the direction of the gas intake velocity of the reaction gas, the other perpendicular to the direction of the gas intake velocity of the reaction gas. The velocity vector perpendicular to the direction of the gas intake velocity of the reaction gas will not disappear, not because of superposition, so there will be no point outside the reference point A where the velocity vector sum is 0. The location where the influence of the effect is most significant is the region near the left radius of the wafer 400.

The relative vector distribution in the radius direction shown in FIG. 3 can be formed by superimposing the vector sums of velocities of the points on the wafer 400 that have the same distance from the center O of the wafer 400 and the gas intake velocity of the reaction gas. Referring to FIG. 3, the closer to the edge region on the wafer 400, the larger the vector sum of the velocity of the wafer 400 and the gas intake velocity of the reaction gas, the smaller the thickness of the gas retention layer, and the smaller the thickness of the film layer formed by deposition. The deposition process includes chemical vapor phase deposition and physical vapor phase deposition, and the chemical vapor phase deposition includes epitaxial growth. The epitaxial growth process is more significantly affected by the uniformity of the thickness of the gas retention layer.

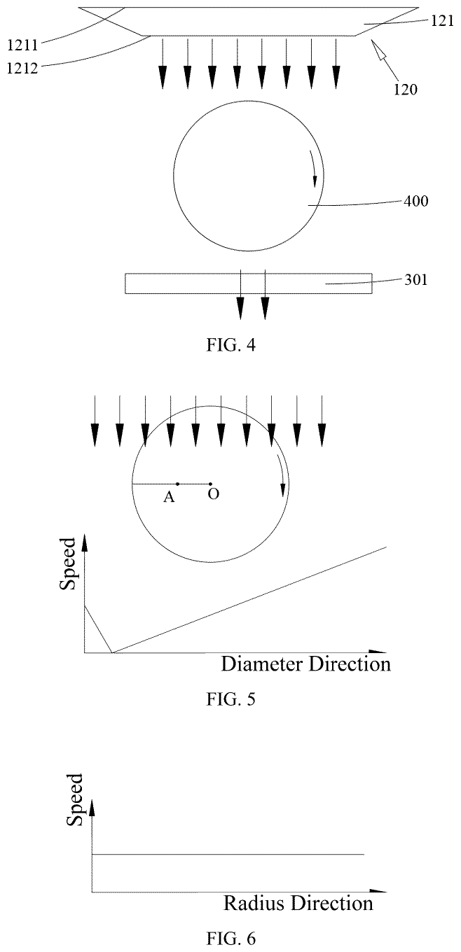

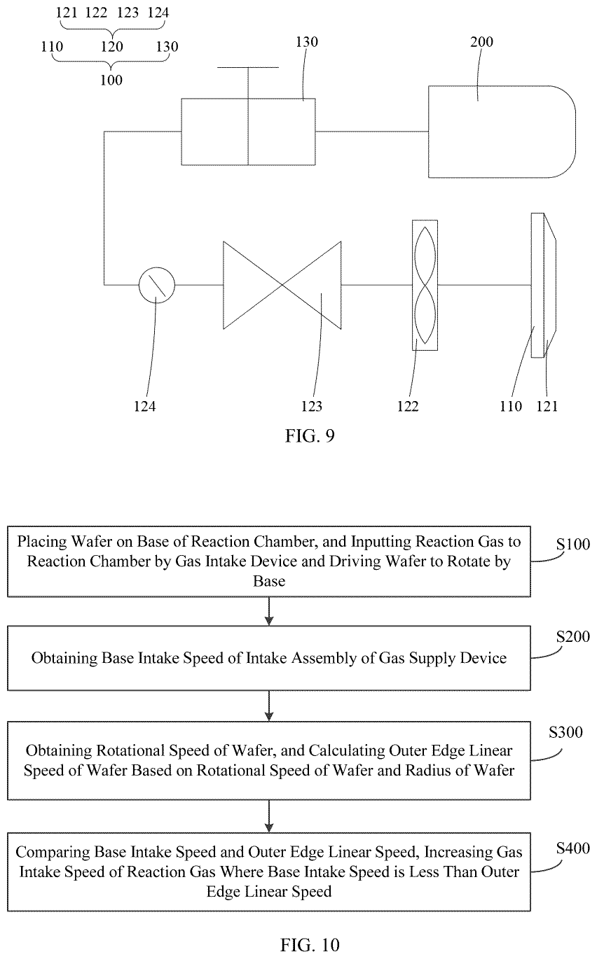

Referring to FIGS. 4 and 9, in this embodiment, the gas intake device 100 is connected to the gas supply device 200. The gas intake device 100 includes a gas intake assembly 110 and a velocity regulation assembly 120. The gas intake assembly 110 is used to input the reaction gas provided by the gas supply device 200 into the reaction chamber. The velocity regulation assembly 120 is provided between the gas intake assembly 110 and the gas supply device 200 or at the gas outlet end of the gas intake assembly 110 for increasing the velocity of the reaction gas (i.e., the gas intake velocity of the reaction gas) that is input into the reaction chamber.

When the velocity regulation assembly 120 is provided between the gas intake assembly 110 and the gas supply device 200, the gas intake assembly 110 is indirectly connected to the gas supply device 200 via the velocity regulation assembly 120. When the velocity regulation assembly 120 is provided at the gas outlet end of the gas intake assembly 110, the gas intake assembly 110 may be directly or indirectly connected to the gas supply device 200.

The gas supply device 200 includes a gas preparation device for preparing the reaction gas or a storage device for storing the reaction gas. The reaction chamber includes an gas outlet, and the gas intake assembly 110 and the gas outlet 301 of the reaction chamber are provided on opposite sides of the reaction chamber.

Referring to FIG. 5, the velocity of the reaction gas can be increased by the velocity regulation assembly 120, so that the vector sum of the velocity of any point on the wafer 400 and the gas intake velocity of the reaction gas is not 0. The relative velocity distribution in the radius direction shown in FIG. 6 can be formed by superimposing the vector sums of velocities of the points on the wafer 400 that have the same distance from the center O of the wafer 400 and the gas intake velocity of the reaction gas. Referring to FIG. 6, the vector sums of the velocities of different positions from the center O of the wafer 400 to the edge region of the wafer 400 and the gas intake velocity of the reaction gas are equal, i.e., the reaction gas retention layer on the wafer 400 is uniformly distributed.

In some technical solutions, the reaction gas is input into the reaction chamber along a first direction, and the compensation gas is input into the reaction chamber along a second direction, the second direction is perpendicular to the first direction. Since the solution of inputting the compensation gas is adopted, although the problem of the unevenness of the thickness of the deposited film layer can be improved at a certain extent, an input of the compensation gas increases the total reaction gas, which leads to a great increase in the difficulty of maintaining the process parameters of the reaction gas. Inputting the compensation gas can only compensate for the thickness of the film layer at the edge region of the wafer 400, and cannot guarantee the uniformity of the thickness of the entire film layer.

In this embodiment, the gas intake device 100 is connected to the gas supply device 200. The gas intake device 100 includes a gas intake assembly 110 and a velocity regulation assembly 120. The gas intake assembly 110 is configured to input the reaction gas provided by the gas supply device 200 into the reaction chamber, and the velocity regulation assembly 120 is provided between the gas intake assembly 110 and the gas supply device 200 or at the gas outlet end of the gas intake assembly 110 to increase the velocity of the reaction gas being input into the reaction chamber. By increasing the velocity of the reaction gas being input into the reaction chamber, a point on the wafer 400 where the vector sum of the velocity of the point and the velocity of the reaction gas inlet is 0 can be eliminated, so that the reaction gas retention layer on the wafer 400 is uniformly distributed, thereby improving the uniformity of the thickness of the film layer formed by deposition.

Compared to the technical solution of inputting the compensation gas, the technical solution of the present embodiment does not change the total amount of the reaction gas, but reduces the difficulty of maintaining process parameters of the reaction gas, and increases the velocity of the reaction gas being input into the reaction chamber is increased, such that the entire reaction gas retention layer on the wafer 400 is uniformly distributed, thereby improving the uniformity of the thickness of the entire surface film layer.

Referring to FIGS. 4 and 9, the velocity regulation assembly 120 includes a rectifier cover 121, the rectifier cover 121 includes a gas inlet and a gas outlet, and the flow area of the gas inlet 1211 of the rectifier cover is larger than that of the gas outlet 1212 of the rectifier cover. The flow area of the reaction gas is reduced and the velocity of the reaction gas is increased. And the flow of the reaction gas being input into the reaction chamber remains constant because the flow of gas supplied by the gas supply device 200 remains constant. Preferably, the rectifier cover 121 may be a conical or quadrangular conical structure.

It is to be noted that the rectifier cover 121 may be of a conical or quadrangular-conical structure, but is not limited thereto, and the rectifier cover 121 may be any other structure of the rectifier cover 121, as long as it is ensured that the flow area of the gas inlet 1211 of the rectifier cover is larger than that of the gas outlet 1212 of the rectifier cover.

The velocity regulation assembly 120 includes a rectifier cover 121, and the flow area of the gas inlet 1211 of the rectifier cover is larger than that of the gas outlet 1212 of the rectifier cover. The velocity of the reaction gas being input into the reaction chamber is increased by the rectifier cover 121, such that the structure is simple and it is conducive to controlling the fabrication cost of the gas intake device 100.

In some embodiments, the rectifier cover 121 is provided at the gas outlet end of the gas intake assembly 110 and integrally connected with the gas intake assembly 110. That is, the gas intake assembly 110 and the rectifier cover 121 may be integrated together or designed as a whole.

It is to be noted that the rectifier cover 121 may be integrally connected with the gas intake assembly 110, but is not limited thereto. The rectifier cover 121 may also be designed as a removable structure to facilitate the maintenance or replacement of different sizes of the rectifier cover 121, which is specifically determined as actual.

The rectifier cover 121 is provided at the gas outlet end of the gas intake assembly 110 and integrally connected with the gas intake assembly 110, such design simplifies the structure of the gas intake device 100 and facilitates control of the fabrication cost of the gas intake device 100.

In some embodiments, a plurality of gas outlets are provided at the gas outlet end of the gas intake assembly 110, and a plurality of the rectifier covers 121 are provided in one-to-one correspondence with the plurality of gas outlets of the gas intake assembly 110, and the gas inlet 1211 of each rectifier cover is connected to the gas outlet of the gas intake assembly 110.

The plurality of gas outlets are provided at the gas outlet end of the gas intake assembly 110, and the plurality of gas outlets input the gas into the reaction chamber, thereby improving the uniformity of gas intake. The rectifier cover 121 is correspondingly provided at each gas outlet of the gas intake assembly 110, which not only increases the gas intake velocity, but also adjusts field distribution of the reaction gas and improves the uniformity of the gas intake through different sizes of the different rectifier covers 121.

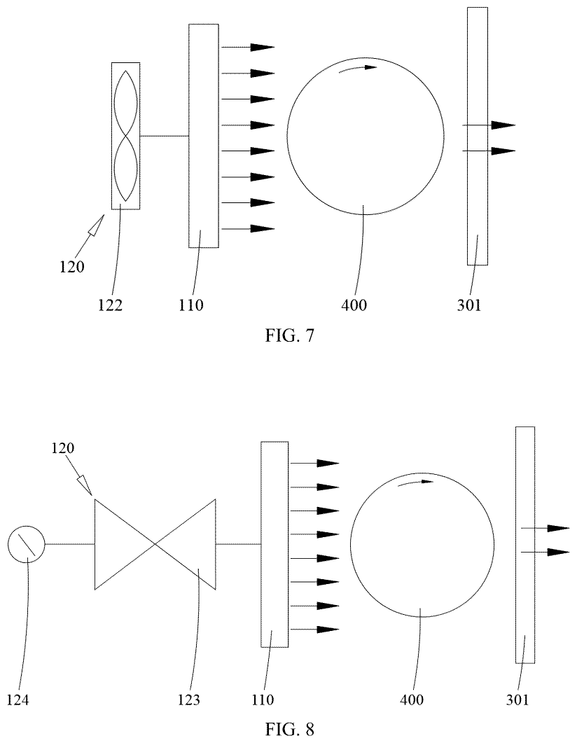

In some embodiments, referring to FIGS. 7 and 9, the velocity regulation assembly 120 includes a wind paddle 122 provided between the gas supply device 200 and the gas intake assembly 110. The rotation of the wind paddle 122 can do work on the reaction gas, thereby increasing the velocity of the reaction gas. And the flow of the reaction gas being input into the reaction chamber remains constant due to the constant flow of the gas supplied from the gas supply device 200.

The wind paddle 122 is provided between the gas supply device 200 and the gas intake assembly 110. Compared to increasing the velocity of the reaction gas through the rectifier cover 121, the velocity of the reaction gas can be controlled in a larger range by controlling the rotation velocity of the wind paddle 122, and the adjustment of the velocity of the reaction gas is achieved easily and the fabrication cost of the gas intake device 100 is not significantly increased.

In some embodiments, referring to FIGS. 8 and 9, the velocity regulation assembly 120 includes a pressure control valve 123 provided between the gas supply device 200 and the gas intake assembly 110. By adjusting the flow area of the reaction gas at the pressure control valve 123, the gas pressure at the front end of the gas intake assembly 110 can be adjusted, thereby adjusting the velocity of the reaction gas.

The pressure control valve 123 is provided between the gas supply device 200 and the gas intake assembly 110. Compared to increasing the velocity of the reaction gas through the rectifier cover 121, the velocity of the reaction gas can be increased in a larger range by adjusting the pressure at the front end of the gas intake assembly 110, and the velocity of the reaction gas is achieved easily and the fabrication cost of the gas intake device 100 is not significantly increased.

In some embodiments, a pressure control valve 123 is provided between the gas supply device 200 and the gas intake assembly 110. Compared to increasing the velocity of the reaction gas through the rectifier cover 121, the velocity of the reaction gas can be adjusted in a larger range by adjusting the gas pressure at the front end of the gas intake assembly 110, and the adjustment of the velocity of the reaction gas is achieved easily and the fabrication cost of the gas intake device 100 is not significantly increased.

In some embodiments, a pressure control valve 123 is provided between the gas supply device 200 and the gas intake assembly 110. And the velocity regulation assembly 120 includes a pressure sensor 124 provided in a pipe between the pressure control valve 123 and the gas supply device 200 or a pipe between the pressure control valve 123 and the gas intake assembly 110.

The pressure sensor 124 is provided between the gas intake assembly 110 and the gas supply device 200. The pressure sensor 124 can monitor the gas pressure at the front end of the gas intake assembly 110, and the pressure control valve 123 can adjust the gas pressure at the front end of the gas intake assembly 110 based on the gas pressure measured by the pressure sensor 124, so as to regulate the velocity of the reaction gas more accurately.

It is readily understood that the pressure control valve 123 may adjust the gas pressure at the front end of the gas intake assembly 110 based on the gas pressure measured by the pressure sensor 124, but is not limited thereto, and the pressure control valve 123 may also adjust the velocity of the reaction gas according to the gas intake flow and other process parameters, which are specifically determined as actual.

In some embodiments, referring to FIG. 9, the velocity regulation assembly 120 includes at least two of the rectifier cover 121, the wind paddle 122, and the pressure control valve 123. The rectifier cover 121 includes a gas inlet and a gas outlet. The flow area of the gas inlet 1211 of the rectifier cover is larger than that of the gas outlet 1212 of the rectifier cover, and the rectifier cover 121 is provided at the gas outlet end of the gas intake assembly 110 and is connected to the gas outlet of the gas intake assembly 110. The wind paddle 122 and the pressure control valve 123 both are provided between the gas supply device 200 and the gas intake assembly 110.

The velocity of the reaction gas can be increased by any one of the rectifier cover 121, the wind paddle 122 and the pressure control valve 123. The velocity regulation assembly 120 includes at least two of the rectifier cover 121, the wind paddle 122 and the pressure control valve 123, such as includes the rectifier cover 121 and the wind paddle 122, or the wind paddle 122 and the pressure control valve 123, or the rectifier cover 121 and the pressure control valve 123, i.e., the velocity regulation assembly 120 is redundantly designed. By such design, one of the velocity regulation structures, such as the rectifier cover 121, the wind paddle 122 or the pressure control valve 123 fails or the velocity regulation doesn't reach a set value, the other velocity regulation structures can replace the failed velocity regulation structure or compensate for not substandard velocity regulation, thereby enhancing the reliability of the gas intake device 100.

In some embodiments, the velocity regulation assembly 120 includes at least a wind paddle 122 and a pressure control valve 123. The gas supply device 200, the pressure control valve 123, the wind paddle 122, and the gas intake assembly 110 are connected sequentially. That is, when the velocity regulation assembly 120 includes the wind paddle 122 and the pressure control valve 123, the pressure control valve 123 may be provided at a front end and the wind paddle 122 may be provided at a rear end.

When the velocity regulation assembly 120 includes the wind paddle 122 and the pressure control valve 123. The pressure control valve 123 is provided at the front end and the wind paddle 122 is provided at the rear end, such design can avoid the pressure control valve 123 from affecting the working efficiency of the wind paddle 122.

It is to be noted that when the velocity regulation assembly 120 includes the wind paddle 122 and the pressure control valve 123, the pressure control valve 123 may be provided at a front end and the wind paddle 122 may be provided at a rear end, but is not limited thereto. The pressure control valve 123 may also be provided at a rear end and the wind paddle 122 may also be provided at a front end, which is specifically determined as actual.

Referring to FIG. 9, the gas intake device 100 further includes a gas flow controller 130 provided between the gas supply device 200 and the velocity regulation assembly 120.

The gas flow controller 130 is provided between the gas supply device 200 and the velocity regulation assembly 120. The gas flow controller 130 can adjust the gas intake flow of the gas intake device 100 to ensure that the flow of the reaction gas being input into the reaction chamber remains constant when the velocity regulation assembly 120 increases the velocity of the reaction gas. In addition, the gas intake flow of the gas intake device 100 can be adjusted through the gas flow controller 130, which is simpler to control compared to adjusting the gas intake flow through the gas supply device 200.

It is to be noted that the gas intake device 100 may include the gas flow controller 130, but is not limited thereto, and the gas flow controller 130 may be integrated with the gas supply device 200, or the gas flow controller 130 may be omitted, and the gas intake flow may be controlled through the gas supply device 200, which is specifically determined as actual.

The present application also provides a thin film deposition device, which includes the above-disclosed gas intake device 100. The thin film deposition device also includes necessary components such as a gas supply device 200 and a reaction chamber. The gas intake device 100 connects the gas supply device 200 and the reaction chamber, and inputs reaction gas prepared or stored by the gas supply device 200 into the reaction chamber. The thin film deposition device may include a chemical vapor phase deposition device and a physical vapor phase deposition device, and the chemical vapor phase deposition device includes an epitaxial growth device.

In this embodiment, the thin film deposition device includes a gas intake device 100, which includes a gas intake assembly 110 and a velocity regulation assembly 120. The gas intake assembly 110 is used to input the reaction gas provided by the gas supply device 200 into the reaction chamber, and the velocity regulation assembly 120 is provided between the gas intake assembly 110 and the gas supply device 200 or at the gas outlet end of the gas intake assembly 110, for increasing the reaction velocity of the reaction gas being input into the reaction chamber. By increasing the velocity of the reaction gas being input into the reaction chamber, a point on the wafer 400 where the vector sum of the velocity of the point and the gas intake velocity of the reaction gas is 0 can be eliminated, so that the reaction gas retention layer on the wafer 400 is uniformly distributed, thereby improving the uniformity of the thickness of the film layer formed by deposition.

The present application also provides a thin film deposition method, as shown in FIGS. 1 and 10, the thin film deposition method includes:

S100: providing a thin film deposition device. The thin film deposition device includes a gas supply device 200, a gas intake device 100, and a reaction chamber connected in sequence. A wafer 400 is placed on a base of the reaction chamber, the gas intake device 100 inputs the reaction gas into the reaction chamber and the wafer 400 is driven through the base to rotate.

The gas intake device 100 includes a gas intake assembly 110, and the gas intake assembly 110 and a gas outlet 301 of the reaction chamber are located on opposite sides of the reaction chamber.

S200: obtaining a base intake velocity of an intake assembly 110 of the gas supply device 200. The base intake velocity is positively correlated with a flow of the reaction gas supplied by the gas supply device, and the base intake velocity is negatively correlated with a flow area of the gas intake assembly.

It is to be noted that under the condition that the gas intake assembly 110 and the diameter of the pipe that connects the gas intake assembly 110 and the gas supply device 200 remain unchanged, and the base gas intake velocity is determined by the flow of the reaction gas provided by the gas supply device 200.

S300: obtaining a rotational velocity of the wafer 400, and calculating an outer edge linear velocity of the wafer 400 based on the rotational velocity of the wafer 400 and a radius of the wafer 400;

S400: comparing the base intake velocity and the outer edge linear velocity, increasing a gas intake velocity of the reaction gas where the base intake velocity is less than the outer edge linear velocity.

By increasing the velocity of the reaction gas being input into the reaction chamber, the point on the wafer 400 where the vector sum of the velocity of the point and the gas intake velocity of the reaction gas is 0 can be shifted outwardly or the point on the wafer 400 where the vector sum of the velocity of the point and the gas intake velocity of the reaction gas is 0 can be eliminated, such that the reaction gas retention layer is distributed uniformly on the wafer 400, thereby improving the uniformity of the thickness of the film layer formed by deposition.

In some embodiments, the base gas intake velocity of the gas intake assembly 110 is calculated based on the flow of gas supplied from the gas supply device 200.

It is to be noted that the base gas intake velocity of the gas intake assembly 110 is calculated based on the flow of gas supplied from the gas supply device 200, but is not limited thereto. The base gas intake velocity of the gas intake assembly 110 may also be measured by a sensor, which is specifically determined as actual.

The base gas intake velocity of the gas intake assembly 110 is calculated based on the flow of gas supplied from the gas supply device 200. Therefore, a sensor for detecting the gas velocity is omitted, which may be beneficial in reducing the fabrication cost of the semiconductor device.

In some embodiments, the gas intake velocity of the reaction gas is greater than or equal to the outer edge linear velocity.

When the gas intake velocity of the reaction gas is equal to the outer edge linear velocity of the wafer 400, the point on the wafer 400 where the vector sum of the velocity of the point and the gas intake velocity of the reaction gas is 0 is just eliminated, and under this condition, both the uniformity of the thickness of the film layer formed by deposition can be improved and the efficiency of deposition of the film layer can be ensured. It should be appreciated that the gas intake velocity of the reaction gas may also be slightly greater than the outer edge linear velocity of the wafer 400 in order to eliminate errors.

In some embodiments, the gas intake device 100 includes a wind paddle 122 provided between the gas supply device 200 and the gas intake assembly 110, and the method of increasing the gas intake velocity of the reaction gas includes: controlling the wind paddle 122 to open. Alternatively, the gas intake device 100 includes a pressure control valve 123 provided between the gas supply device 200 and the gas intake assembly 110, and the method of increasing the gas intake velocity of the reaction gas includes: reducing the flow area of the reaction gas at the pressure control valve 123.

The wind paddle 122 is controlled to start, the rotation of the wind paddle 122 may do work on the reaction gas, thereby increasing the velocity of the reaction gas. Reduction of the flow area of the reaction gas at the pressure control valve 123 increases the gas pressure at the front end of the gas intake assembly 110, thereby increasing the velocity of the reaction gas. By increasing the velocity of the reaction gas being input into the reaction chamber, a point on the wafer 400 where the vector sum of the velocity of the point and the velocity of the reaction gas inlet is 0 can be eliminated, such that the reaction gas retention layer is distributed uniformly on the wafer 400, thereby improving the uniformity of the thickness of the film layer formed by deposition.

In some embodiments, the gas intake device 100 includes a wind paddle 122 and a pressure control valve 123, and the wind paddle 122 and the pressure control valve 123 are both provided between the gas supply device 200 and the gas intake assembly 110, and the method of increasing the gas intake velocity of the reaction gas includes:
reducing a flow area of the reaction gas at the pressure control valve 123, and controlling the wind paddle 122 to start when the pressure control valve 123 fails or the flow area of the reaction gas at the pressure control valve 123 is reduced to a limit position.

Preferably, the pressure control valve 123 is used to increase the gas intake velocity of the reaction gas, which allows the pressure of the boundary conditions to be fixed, and the gas intake velocity of the reaction gas is controlled more simply and more accurately.

It should be noted that the pressure control valve 123 may be preferentially used to increase the gas intake velocity of the reaction gas, and the wind paddle 122 is used as a backup for the pressure control valve 123, and the wind paddle 122 is turned on when the pressure control valve 123 fails or reaches the control limitation, but is not limited thereto, and it is also possible to control the wind paddle 122 to be turned on while reducing the flow area of the reaction gas at the pressure control valve 123, which is specifically determined as actual.

In some embodiments, the method of increasing the gas intake velocity of the reaction gas includes:
mounting a rectifier cover 121 at a gas inlet end or a gas outlet end of the gas intake assembly 110. The rectifier cover includes a gas inlet and a gas outlet, a flow area of the gas inlet 1211 of the rectifier cover is a greater than that of the gas outlet 1212 of the rectifier cover.

By reducing the flow area of the reaction gas, the gas intake velocity of the reaction gas can be increased. By increasing the velocity of the reaction gas being input into the reaction chamber, a point on the wafer 400 where the vector sum of the velocity of the point and the velocity of the reaction gas intake is 0 can be eliminated, such that the reaction gas retention layer is distributed uniformly on the wafer 400, thereby improving the uniformity of the thickness of the film layer formed by the deposition.

In some embodiments, the method of increasing the gas intake velocity of the reaction gas includes:
reducing the pressure at the gas outlet 301 of the reaction chamber.

The gas intake assembly 110 and the gas outlet 301 of the reaction chamber are located on opposite sides of the reaction chamber, and the pressure at the gas intake assembly 110 is greater than the pressure at the gas outlet 301 of the reaction chamber, and the reaction gas flows from the gas intake assembly 110 to the gas outlet 301 of the reaction chamber. Appropriate reduction of the pressure at the gas outlet 301 of the reaction chamber can increase the pressure difference between the gas intake assembly 110 and the gas outlet 301 of the reaction chamber, which serves to increase the gas intake velocity of the reaction gas. In addition, while reducing the pressure at the gas outlet 301 of the reaction chamber, the flow of gas supplied from the gas supply device 200 may be appropriately increased.

It is to be noted that the increase in the flow of gas supplied from the gas supply device 200 and the decrease in the pressure at the gas outlet 301 of the reaction chamber form a correspondence relationship, which can be calculated by practical use or simulation, and the gas intake flow of the gas supply device 200 and the pressure at the gas outlet 301 of the reaction chamber can be synchronously adjusted based on the correspondence relationship, so as to prevent changes in the thickness of the deposited film layer caused by reducing the pressure at the gas outlet 301 of the reaction chamber.

In some embodiments, the method of increasing the gas intake velocity of the reaction gas includes:
increasing a temperature of the reaction gas within the gas intake device 100.

Increase of the temperature of the reaction gas within the gas intake device 100 can increase the pressure of the reaction gas within the gas intake device 100. The gas intake assembly 110 and the gas outlet 301 of the reaction chamber are located on opposite sides of the reaction chamber, and the pressure at the gas intake assembly 110 is greater than the pressure at the gas outlet 301 of the reaction chamber, and the reaction gas flows from the gas intake assembly 110 to the gas outlet 301 of the reaction chamber. Increase of the pressure of the reaction gas in the gas intake device 100 can increase the pressure difference between the gas intake assembly 110 and the gas outlet 301 of the reaction chamber, which serves to increase the gas intake velocity of the reaction gas.

The terms “first”, “second”, etc. are used only for descriptive purposes and are not to be understood as indicating or implying relative importance or implicitly specifying the number of technical features indicated. Accordingly, a feature defined with “first”, “second”, etc. may expressly or implicitly include one or more such features. In the description of the present application, “more than one” means two or more, unless otherwise expressly and specifically limited.

In the present application, unless otherwise expressly specified and limited, the terms “assembly”, “connection”, etc. are to be understood in a broad sense, for example, they may be fixed, removable or integral, or mechanically connected or electrically connected, or may be a direct connection or an indirect connection through an intermediate medium, a connection within two elements or an interaction between two elements. For those skilled in the art, the specific meanings of the above terms in the present application may be understood based on actual situation.

In the description of the present specification, the description with reference to the terms “some embodiments”, “exemplarily”, etc. means that specific features, structures, materials, or characteristics described in conjunction with the embodiments or examples are included in at least one embodiment or example of the present application. In this specification, schematic expressions of the above terms do not necessarily refer to the same embodiment or example. Moreover, the specific features, structures, materials, or characteristics described may be combined in a suitable manner in any one or more of the embodiments or examples. Furthermore, without contradicting each other, those skilled in the art may combine and combine different embodiments or examples and features of different embodiments or examples described in this specification.

Although the embodiments of the present application have been shown and described above, it is understood that the above embodiments are exemplary and cannot be construed as a limitation to the present application, and that those skilled in the art may make changes, modifications, substitutions, and variations of the above embodiments within the scope of the present application, and therefore, any changes or modifications made in accordance with the claims and the specification of the present application shall fall within the scope of the present application.

What is claimed is:

1. A gas intake device, connected to a gas supply device, comprising:
a gas intake assembly, for inputting reaction gas supplied by the gas supply device into a reaction chamber; and
a velocity regulation assembly, provided between the gas intake assembly and the gas supply device or at a gas outlet end of the gas intake assembly, for increasing a velocity of the reaction gas being input into the reaction chamber;
wherein the velocity regulation assembly comprises at least one rectifier cover, and each rectifier cover comprises a gas inlet and a gas outlet, wherein a flow area of the gas inlet of each rectifier cover is greater than a flow area of the gas outlet of each rectifier cover; and
the at least one rectifier cover is provided at the gas outlet end of the gas intake assembly.

2. The gas intake device according to claim 1, wherein the at least one rectifier cover is integrally connected with the gas intake assembly.

3. The gas intake device according to claim 1, wherein a plurality of gas outlets are provided at the gas outlet end of the gas intake assembly, and a plurality of rectifier covers are provided in one-to-one correspondence with the plurality of gas outlets of the gas intake assembly, and gas inlets of the plurality of rectifier covers are connected to the plurality of gas outlets of the gas intake assembly correspondingly one-to-one.

4. The gas intake device according to claim 1, wherein the velocity regulation assembly comprises a wind paddle provided between the gas supply device and the gas intake assembly.

5. The gas intake device according to claim 1, wherein the velocity regulation assembly comprises a pressure control valve provided between the gas supply device and the gas intake assembly.

6. The gas intake device according to claim 5, wherein the velocity regulation assembly comprises a pressure sensor provided in a pipe between the pressure control valve and the gas supply device or between the pressure control valve and the gas intake assembly.

7. The gas intake device according to claim 1, wherein the velocity regulation assembly comprises at least two of a rectifier cover, a wind paddle and a pressure control valve;
wherein the rectifier cover comprises a gas inlet and a gas outlet, a flow area of the gas inlet of the rectifier cover is greater than a flow area of the gas outlet of the rectifier cover, and the rectifier cover is provided at the gas outlet end of the gas intake assembly and connected to a gas outlet of the gas intake assembly; and
wherein the wind paddle and the pressure control valve are provided between the gas supply device and the gas intake assembly.

8. The gas intake device according to claim 7, wherein the velocity regulation assembly comprises at least the wind paddle and the pressure control valve; and
wherein the gas supply device, the pressure control valve, the wind paddle and the gas intake assembly are connected in sequence.

9. The gas intake device according to claim 1, wherein the gas intake device further comprises a gas flow controller provided between the gas supply device and the velocity regulation assembly.

10. A thin film deposition device, comprising a gas intake device, and a reaction chamber connected to the gas intake device;
wherein the gas intake device connected to a gas supply device comprises:
a gas intake assembly, for inputting reaction gas supplied by the gas supply device into the reaction chamber; and
a velocity regulation assembly, provided between the gas intake assembly and the gas supply device or at a gas outlet end of the gas intake assembly, for increasing a velocity of the reaction gas being input into the reaction chamber;
wherein the velocity regulation assembly comprises at least one rectifier cover, and each rectifier cover comprises a gas inlet and a gas outlet, wherein a flow area of the gas inlet of each rectifier cover is greater than a flow area of the gas outlet of each rectifier cover; and
the at least one rectifier cover is provided at the gas outlet end of the gas intake assembly.

11. A thin film deposition method, comprising:
providing a thin film deposition device, wherein the thin film deposition device comprises a gas supply device, a gas intake device and a reaction chamber connected in sequence;
placing a wafer on a base of the reaction chamber, and inputting reaction gas to the reaction chamber by a gas intake assembly and driving the wafer to rotate by the base;
obtaining a base intake velocity of an intake assembly of the gas supply device, wherein the base intake velocity is positively correlated with a flow of the reaction gas supplied by the gas supply device, and the base intake velocity is negatively correlated with a flow area of the gas intake assembly;
obtaining a rotational velocity of the wafer, and calculating an outer edge linear velocity of the wafer based on the rotational velocity of the wafer and a radius of the wafer; and
comparing the base intake velocity and the outer edge linear velocity, increasing a gas intake velocity of the reaction gas where the base intake velocity is less than the outer edge linear velocity.

12. The thin film deposition method according to claim 11, wherein the gas intake velocity of the reaction gas is greater than or equal to the outer edge linear velocity.

13. The thin film deposition method according to claim 12, wherein the gas intake device comprises a wind paddle provided between the gas intake assembly and the gas supply device, and increasing the gas intake velocity of the reaction gas comprises:
controlling the wind paddle to open; or
wherein the gas intake device comprises a pressure control valve provided between the gas intake assembly and the gas supply device, and increasing the gas intake velocity of the reaction gas comprises:
reducing the flow area of the reaction gas at the pressure control valve.

14. The thin film deposition method according to claim 13, wherein the gas intake device comprises the wind paddle and the pressure control valve provided between the gas intake assembly and the gas supply device, wherein increasing the gas intake velocity of the reaction gas comprises:
reducing the flow area of the reaction gas at the pressure control valve, and controlling the wind paddle to open when the pressure control valve fails or when the flow area of the reaction gas at the pressure control valve is reduced to a limit position.

15. The thin film deposition method according to claim 11, wherein increasing the gas intake velocity of the reaction gas comprises:
mounting a rectifier cover at a gas inlet end or a gas outlet end of the gas intake assembly, wherein the rectifier cover comprises a gas inlet and a gas outlet, a flow area of the gas inlet of the rectifier cover is greater than a flow area of the gas outlet of the rectifier cover.

16. The thin film deposition method according to claim 11, wherein increasing the gas intake velocity of the reaction gas comprises:
reducing a pressure at a gas outlet of the reaction chamber.

17. The thin film deposition method according to claim 11, wherein increasing the gas intake velocity of the reaction gas comprises:
increasing a temperature of the reaction gas in the gas intake device.

18. The thin film deposition method according to claim 11, wherein the base intake velocity of the gas intake assembly is calculated based on a flow of gas supplied from the gas supply device.
